(19) United States
(12) Patent Application Publication
(10) Pub. No.: US 2025/0308887 A1
(43) Pub. Date: Oct. 2, 2025

(54) METHOD OF EMBEDDING RECESS AND PLASMA PROCESSING APPARATUS

(71) Applicant: Tokyo Electron Limited, Tokyo (JP)

(72) Inventors: Takafumi NOGAMI, Yamanashi (JP); Kenichi KOTE, Yamanashi (JP)

(21) Appl. No.: 19/234,797

(22) Filed: Jun. 11, 2025

Related U.S. Application Data
(63) Continuation of application No. PCT/JP2023/043067, filed on Dec. 1, 2023.

(30) Foreign Application Priority Data
Dec. 15, 2022 (JP) 2022-200113

(51) Int. Cl. H01L 21/02; H01J 37/32; H01L 21/311

(52) U.S. Cl. CPC H01L 21/0228; H01J 37/32146; H01L 21/02208; H01L 21/02274; H01L 21/0234; H01L 21/31116

(57) ABSTRACT

A method of embedding a recess includes: preparing a substrate having a recess on a stage in a process chamber; applying a pulsed first DC voltage to the stage to form a dielectric film in the recess by a plasma generated from a gas containing a raw material gas supplied into the process chamber; applying a pulsed second DC voltage to the stage to etch at least a part of the dielectric film formed in the recess by a plasma generated from a gas containing an etchant gas supplied into the process chamber; and repeating the forming of the dielectric film and the etching of the dielectric film. The first DC voltage is set to a predetermined value, and the second DC voltage is a value different from the first DC voltage and is set to a predetermined value.

### CROSS-REFERENCE TO RELATED APPLICATIONS

The present application is a continuation application of International Application No. PCT/JP2023/043067, filed Dec. 1, 2023, which claims priority to Japanese Patent Application No. 2022-200113filed Dec. 15, 2022. The contents of these applications are incorporated herein by reference.

### BACKGROUND

### 1. Field of the Invention

The present disclosure relates to a method of embedding a recess and a plasma processing apparatus.

### 2. Description of the Related Art

For example, Japanese Translation of PCT International Application Publication No. JP-T-2021-528848discloses a plasma processing apparatus. In the plasma processing apparatus, the plasma etching process is performed by exposing the substrate to a gas mixture of a first precursor and a second precursor while the plasma formed by a first pulse RF power is simultaneously present in the process chamber to form a dielectric layer on a patterned feature of the substrate; exposing the dielectric layer to a first plasma treatment using a gas mixture of nitrogen and helium in the process chamber; and exposing the dielectric layer to a plasma formed from a gas mixture of a fluorine-containing precursor and a carrier gas formed in the process chamber by a second pulse RF power.

For example, Japanese Unexamined Patent Application Publication No. H7-161703, Japanese Unexamined Patent Application Publication No. H11-340217, and Japanese Unexamined Patent Application Publication No. 2019-192733 disclose that a high-frequency bias power is supplied when a step of forming a desired film and a step of etching a part of the desired film are repeated.

### SUMMARY

A method of embedding a recess according to an aspect of the present disclosure includes: preparing a substrate having a recess on a stage in a process chamber; applying a pulsed first direct current (DC) voltage to the stage to form a dielectric film in the recess by a plasma generated from a gas containing a raw material gas supplied into the process chamber; applying a pulsed second DC voltage to the stage to etch at least a part of the dielectric film formed in the recess by a plasma generated from a gas containing an etchant gas supplied into the process chamber; and repeating the forming of the dielectric film and the etching of the dielectric film, wherein the first DC voltage is set to a value in which a potential of the substrate in the forming of the dielectric film is selectively controlled to a potential that makes the dielectric film have a desired shape, and the second DC voltage is a value different from the first DC voltage and is set to a value in which a potential of the substrate in the etching of the dielectric film is selectively controlled to a potential that makes the dielectric film have a desired shape.

### BRIEF DESCRIPTION OF THE DRAWINGS

FIG. 1 is a schematic cross-sectional diagram illustrating an example of a plasma processing apparatus according to one embodiment;

FIG. 2 is a schematic cross-sectional diagram illustrating an example of a film formed by a conventional method of embedding a recess;

FIG. 3 is an example of a scanning electron microscope (SEM) image of a film formed by a conventional method of embedding a recess;

FIG. 4 is a schematic cross-sectional diagram illustrating an example of a film formed by a method of embedding a recess according to one embodiment;

FIG. 5 is an example of an SEM image of a film formed by a method of embedding a recess according to one embodiment;

FIG. 6 is a flowchart illustrating an example of a method of embedding a recess according to one embodiment;

FIG. 7 is a diagram illustrating an example of a direct current (DC) voltage pulse waveform in a film forming process and an etching process according to one embodiment;

FIG. 8 is an example of an SEM image of a film after a film forming process according to one embodiment;

FIG. 9 is an example of an SEM image of a film after a film forming process according to one embodiment;

FIGS. 10A, 10B, and 10C are diagrams illustrating an example of a result of varying the pulse frequency, duty ratio, and etching time in an etching process according to one embodiment;

FIGS. 11A, 11B, and 11C illustrate an example of a DC pulse voltage and a substrate potential according to one embodiment;

FIG. 12 illustrates an example of a DC pulse voltage and a tendency of a substrate potential to be selected according to one embodiment;

FIG. 13 illustrates an example of a DC pulse voltage and a tendency of a substrate potential to be selected according to one embodiment; and

FIG. 14 illustrates an example of bottom thickness relative to top thickness when a DC pulse voltage and an RF pulse power are used.

### DETAILED DESCRIPTION OF THE DISCLOSURE

Hereinafter, an embodiment of the present disclosure will be described with reference to the drawings. In each of the drawings, the same components are denoted by the same reference numerals, and duplicate descriptions may be omitted.

### Plasma Processing Apparatus

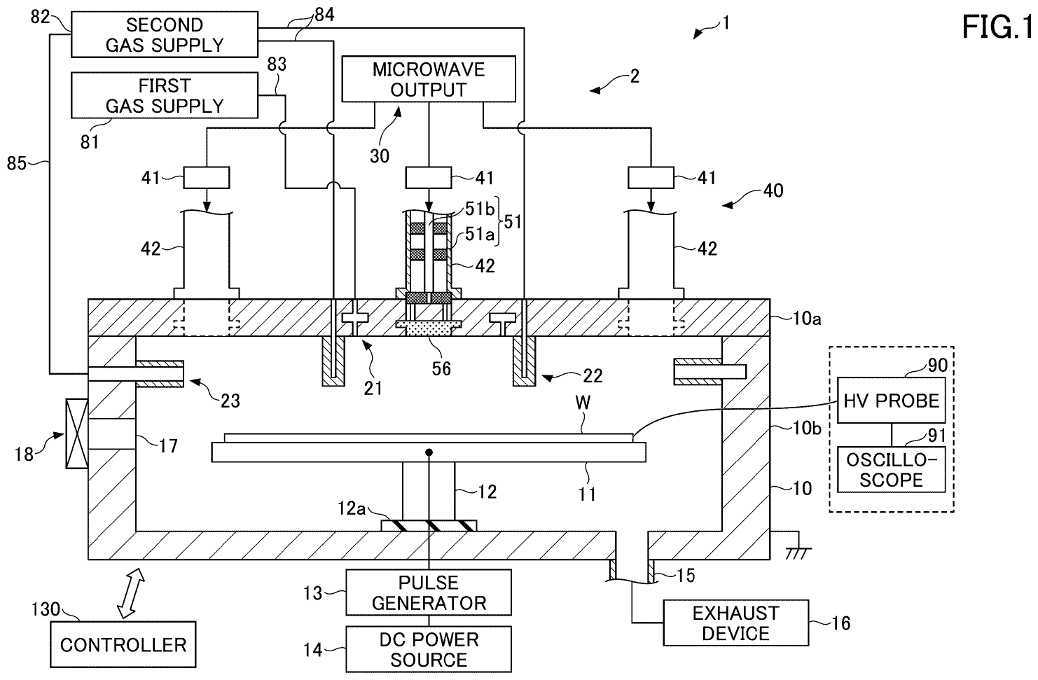

A configuration example of a plasma processing apparatus for executing a method of embedding according to the present embodiment will be described with reference to FIG. 1. FIG. 1 is a diagram illustrating a configuration example of a plasma processing apparatus 1 including a microwave plasma source according to one embodiment.

The plasma processing apparatus 1 includes a process chamber 10 and a plasma source 2. The process chamber 10 has a substantially cylindrical shape made of an airtight metallic material such as aluminum and is grounded. The plasma source 2 introduces microwaves into the process chamber 10 to form a surface wave plasma. A top wall 10a of the process chamber 10 is constructed by fitting dielectric members (hereinafter referred to as dielectric windows 56) of a plurality of microwave radiation mechanisms 42 into a metal body. Thus, the plasma source 2 introduces microwaves into the process chamber 10 via the plurality of dielectric windows 56 of the top wall 10a.

The plasma processing apparatus 1 has a controller 130. The controller 130 is, for example, a computer and has a program storage (not illustrated). The program storage stores a program for controlling the processing of a substrate W, an example of which is a semiconductor wafer, in the plasma processing apparatus 1. The program may be recorded in a computer-readable storage medium, such as a computer-readable hard disk (HD), a flexible disk (FD), a compact disk (CD), a magnet optical desk (MO), or a memory card, and installed in the controller 130 from the storage medium.

In the process chamber 10, a stage 11 for horizontally supporting the substrate W is provided in a state supported by a cylindrical support member 12 erected at the center of the bottom of the process chamber 10 via an insulating member 12a. The materials constituting the stage 11 and the support member 12 are, for example, a metal such as aluminum whose surface is anodized, or an insulating material (such as a ceramic) having a high-frequency electrode inside.

Although not illustrated, the stage 11 is provided with a temperature control mechanism, a gas passage for supplying heat transfer gas to the back surface of the substrate W, and lifting pins that move up and down to transport the substrate W. Furthermore, an electrostatic chuck for electrostatic adsorption of the substrate W may be provided.

A direct current (DC) power source 14 is connected to the stage 11 via a pulse generator 13. A DC voltage of negative polarity is supplied from the DC power source 14, and the DC voltage is pulsed and output by the pulse generator 13. When the DC voltage is on, ions in the plasma are attracted toward the substrate W, thereby contributing to film quality improvement and in-plane uniformity. The pulsed DC voltage is also called “DC pulse voltage”.

An exhaust pipe 15 is connected to the bottom of the process chamber 10, and an exhaust device 16 including a vacuum pump is connected to the exhaust pipe 15. By operating the exhaust device 16, the inside of the process chamber 10 can be exhausted, and the inside of the process chamber 10 can be depressurized and set to a predetermined pressure. A side wall 10b of the process chamber 10 is provided with a load/unload port 17 for loading and unloading the substrate W, and a gate valve 18 for opening and closing the load/unload port 17.

The plasma processing apparatus 1 includes a first gas shower 21 for discharging a predetermined gas into the process chamber 10 from the top wall 10a of the process chamber 10, and a second gas shower 22 for introducing gas from a position between the top wall 10a and the stage 11. Furthermore, the plasma processing apparatus 1 includes a third gas shower 23 for introducing gas from a position between the top wall 10a and the stage 11 and outward relative to the second gas shower 22 in the process chamber 10.

The first gas shower 21 and the second gas shower 22 are illustrated at positions shifted in the radial direction for convenience in FIG. 1, but they are provided alternately on the same circle. The first gas shower 21 is provided on the top wall of the process chamber 10, and supplies gas carried from a first gas supply 81 through a gas line 83 from a first position. The second gas shower 22 is provided on the top wall of the process chamber 10, and supplies gas carried from a second gas supply 82 through a gas line 84 from a second position lower than the first position. The third gas shower 23 is provided on the side wall 10b of the process chamber 10, and supplies gas carried from the second gas supply 82 through a gas line 85 from a third position lower than the first position.

In the film forming process described later, a raw material gas (a film forming gas) is supplied from the second gas shower 22 and the third gas shower 23. For example, a silicon-containing film of any one of SiO₂, SiN, SiON, SiCN, SiOC, and SiOCN is formed as a dielectric film in a recess formed on a substrate. In this case, gas containing a raw material gas is supplied from the second gas shower 22 and the third gas shower 23. The gas containing the raw material gas includes a silicon-containing gas and a gas containing at least one of nitrogen, oxygen, and carbon. Examples of the silicon-containing gas include silicon-containing gases such as silane (SiH₄) gas and dichlorosilane (DCS) gas. Examples of the gas containing at least one of nitrogen, oxygen, and carbon include hydrocarbon gases represented by CₓH_{y} such as C₂H₆ gas, nitrogen-containing gases such as N₂ gas and NH₃ gas, and oxygen-containing gases such as O₂ gas and O₃ gas. The gas containing the raw material gas may further contain a diluent gas such as Ar gas and He gas.

The film forming gas may be supplied from at least one of the second gas shower 22 and the third gas shower 23. Dissociation of the gas can be suppressed by supplying the film forming gas from the second position and/or the third position lower than the first position.

A processing gas other than the film forming gas may be supplied from the first gas shower 21 and the third gas shower 23. An ignition gas may be supplied from at least one of the first gas shower 21 and the third gas shower 23. A diluent gas may be supplied from the first gas shower 21 and/or the third gas shower 23. Examples of the ignition gas and the diluent gas include Ar gas and He gas. NH₃ gas, N₂ gas, and O₂ gas may be supplied from the first gas shower 21. The gas containing the raw material gas joined at the outlet of a gas box (not illustrated) is supplied from the corresponding gas shower into the process chamber 10.

In the etching process described later, a gas containing an etchant gas is supplied from the second gas shower 22 and the third gas shower 23. For example, when etching a silicon-containing film of any one of SiO₂, SiN, SiON, SiCN, SiOC, and SiOCN, the gas containing the etchant gas is supplied from the second gas shower 22 and the third gas shower 23. The gas containing the etchant gas is at least one of Ar gas, a mixed gas of Ar and N₂, a mixed gas of Ar and NH₃, H₂ gas, a mixed gas of H₂ and N₂, or a mixed gas of H₂ and NH₃.

The etchant gas may be supplied from at least one of the first gas shower 21, the second gas shower 22, and the third gas shower 23. Dissociation of the gas can be suppressed by supplying the etchant gas from the second position and/or the third position lower than the first position.

A processing gas other than the etchant gas may be supplied from the first gas shower 21 and the third gas shower 23. An ignition gas may be supplied from at least one of the first gas shower 21 and the third gas shower 23. A diluent gas may be supplied from the first gas shower 21 and/or the third gas shower 23. Examples of the ignition gas and the diluent gas include Ar gas and He gas. NH₃ gas, N₂ gas, and O₂ gas may be supplied from the first gas shower 21. The gas containing the etchant gas joined at the outlet of the gas box (not illustrated) is supplied from the corresponding gas shower into the process chamber 10.

The plasma source 2 includes a microwave output 30 that outputs microwaves by distributing them to a plurality of paths, and a microwave transmitter 40 that transmits the microwaves output from the microwave output 30.

The microwave output 30 includes a microwave power source, a microwave oscillator, an amplifier, and a distributor. The microwave power source supplies power to the microwave oscillator. The microwave oscillator causes, for example, PLL oscillation of microwaves at a predetermined frequency (for example, 860 MHz). The amplifier amplifies the oscillated microwaves. The distributor distributes the microwaves amplified by the amplifier while maintaining impedance matching on both the input and output sides so as to minimize the loss of the microwaves. In addition to 860 MHz, various frequencies ranging from 700 MHz to 3 GHz such as 915 MHz may be used as the frequency of the microwaves.

The microwave transmitter 40 includes a plurality of amplifiers 41 and a plurality of microwave radiation mechanisms 42 provided corresponding to the amplifiers 41. The microwave radiation mechanisms 42 are arranged, for example, in a total of seven units, one at the center of the top wall 10a and six at equal intervals on a circumference centered on the central one. In this example, the microwave radiation mechanisms 42 are arranged such that the distance between the center microwave radiation mechanism 42 and the outer peripheral microwave radiation mechanisms 42 is equal to the distance between the outer peripheral microwave radiation mechanisms 42.

The amplifier 41 guides the microwaves distributed by the distributor to each microwave radiation mechanism 42. The microwave radiation mechanism 42 includes a coaxial tube 51. The coaxial tube 51 includes a coaxial microwave transmission path consisting of a cylindrical outer conductor 51a and a rod-shaped inner conductor 51b provided at the center of the outer conductor 51a. The microwave radiation mechanism 42 includes a feeding antenna (not illustrated) for feeding the microwaves amplified by the amplifier 41 to the coaxial tube 51. Furthermore, the microwave radiation mechanism 42 includes a tuner for matching the impedance of the load with the characteristic impedance of the microwave power source, and an antenna for radiating the microwaves from the coaxial tube into the process chamber 10.

The antenna is provided at the lower end of the coaxial tube 51 and is fitted into the metal portion of the top wall 10a of the process chamber 10. The antenna includes the dielectric window 56. A surface wave plasma is generated in the portion directly under the dielectric window 56 in the process chamber 10 by the microwaves transmitted through the dielectric window 56.

A plurality of plasma sources 2 (the dielectric windows 56) are provided, one in the center of the ceiling and six in the outer periphery. Each of the plurality of plasma sources 2 (the dielectric windows 56) can independently control the microwave power supplied from each plasma source 2. The microwave power supplied from the plasma sources 2 (the dielectric windows 56) in the outer periphery may be higher than or equal to the microwave power supplied from the plasma source 2 in the center.

The method of embedding a recess according to the present embodiment may be performed in the plasma processing apparatus 1 that supplies the microwave power from the plasma source 2 arranged in the top wall of the process chamber 10. Because high-density plasma can be generated while ion energy is suppressed by generating plasma with the microwave power, a high-density film can be formed even in a lower temperature process. The method of embedding a recess includes a film forming process and an etching process, and the film forming process and the etching process are repeated a set number of times.

In the film forming process, the microwave power is supplied into the process chamber 10 to generate plasma of the gas containing the raw material gas. In the film forming process, a pulsed first DC voltage (a first DC pulse voltage) is applied to the stage 11. Thus, a dielectric film is formed in the recess by the plasma of the gas containing the raw material gas.

In the etching process, the microwave power is supplied into the process chamber 10 to generate plasma of the gas containing the etchant gas. In the etching process, a pulsed second DC voltage (a second DC pulse voltage) is applied to the stage 11. Thus, at least a part of the dielectric film formed in the recess is etched by the plasma of the gas containing the etchant gas.

The method of embedding a recess according to the present embodiment is not limited to the configuration of the plasma processing apparatus 1 illustrated in FIG. 1, but may be performed by a plasma chemical vapor deposition (CVD) apparatus.

### Conventional Method of Embedding Recess

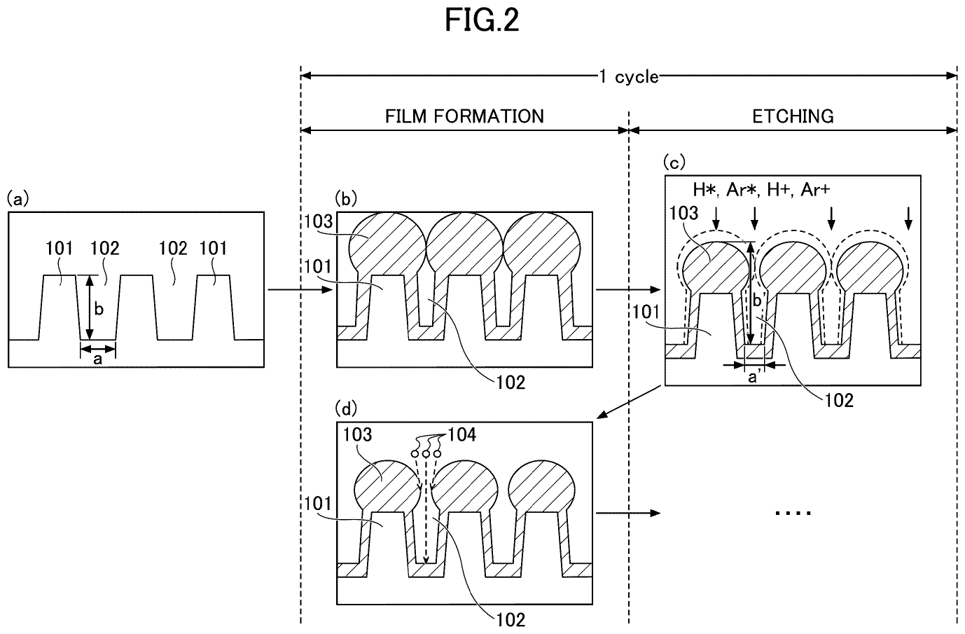

Problems of the conventional method of embedding a recess will be described with reference to FIG. 2. FIG. 2 is a schematic cross-sectional diagram illustrating an example of a dielectric film 103 formed by the conventional method of embedding a recess.

FIG. 2(a) illustrates an example of the substrate W provided in the process chamber 10. FIG. 2(a) illustrates an example of the substrate W in an initial state before a film formation and etching. The substrate W includes a plurality of recesses 102 in a base film 101. Each of the recesses 102 has a top surface, a bottom surface, and a side surface. The recesses 102 may be holes, lines, or trenches. When the width of the bottom surface of the recess 102 in the initial state of FIG. 2(a) is a, and the length (depth) of the side surface is b, the aspect ratio (X) of the recess 102 is represented by b/a.

In the conventional method of embedding a recess, for example, the dielectric film 103 is formed by the CVD method in a film forming process. FIG. 2(b) illustrates the state after the first film formation. The dielectric film 103 is deposited more on the top surface than the bottom surface and the side surface of the recess 102. There is a part where the opening of the recess 102 is blocked by the dielectric film 103, and a void is generated in the recess 102.

After the film formation, etching is performed, and a part of the dielectric film 103 is etched. FIG. 2(c) illustrates the state after the first etching. The top surface, the side surface, and the bottom surface of the dielectric film 103 are etched by the action of H radicals, Ar radicals, H ions, and Ar ions in the plasma, and the opening of the recess 102 can be opened.

The above-described film forming process and etching process are counted as one cycle, and a plurality of cycles of the film forming process and the etching process are repeated. When the width of the bottom surface of the recess 102 after one cycle illustrated in FIG. 2(c) is a′ and the depth of the dielectric film 103 is b′, the aspect ratio (X′) of the recess 102 is represented by b′/a′. When the aspect ratio (X′) of the recess 102 is compared with the aspect ratio (X) in the initial state, X<′ is obtained. That is, when the dielectric film 103 is formed, the aspect ratio becomes larger than the aspect ratio in the initial state, and it becomes difficult to embed the dielectric film 103 in the bottom of the recess 102. The aspect ratio of the recess 102 becomes larger as the number of cycles increases, and as illustrated in FIG. 2(d), active species (precursors) 104 are less likely to enter the recess 102, so that it becomes even more difficult to embed the dielectric film 103.

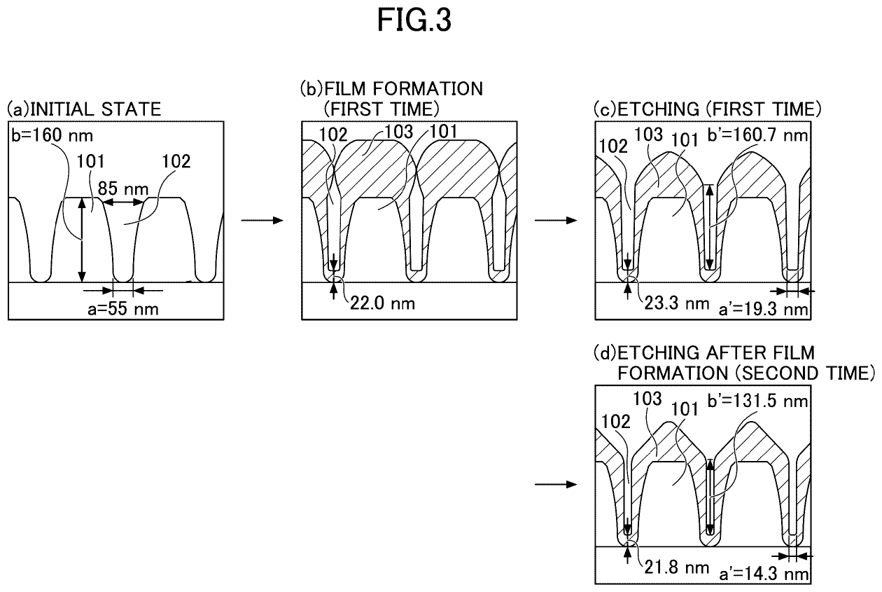

FIG. 3 is a traced image of an example of a scanning electron microscope (SEM) image of the dielectric film 103 formed by the conventional method of embedding a recess. FIG. 3(a) illustrates the initial state of the substrate W before the film formation and etching, in which the width a of the bottom surface of the recess 102 was 55 nm, the length b of the side surface was 160 nm, and the aspect ratio (X) was 2.9. FIG. 3(b) illustrates the state of the film after the first film forming process, and the thickness of the dielectric film 103 at the bottom was 22.0 nm. FIG. 3(c) illustrates the state of the film after the first etching process, and the thickness of the dielectric film 103 at the bottom was 23.3 nm. It is considered that the dielectric film 103 at the sides and the top fell to the bottom during etching. The width a′ of the bottom surface of the recess 102 was 19.3 nm, the depth b′ of the dielectric film 103 was 160.7 nm, and the aspect ratio (X′) was 8.3. Here, the depth b′ of the dielectric film 103 is the length from the bottom surface to the corner of the upper part (near the opening of the recess 102) of the dielectric film 103.

FIG. 3(d) illustrates the state of the film after the second etching process, and the dielectric film 103 of 21.8 nm was formed at the bottom. The width a′ of the bottom surface of the recess 102 was 14.3 nm, the depth b′ was 131.5 nm, and the aspect ratio (X′) was 9.2.

From the above, it was found that in the conventional method of embedding a recess, the aspect ratio increased as the number of cycles increased, and it became difficult to embed the dielectric film 103 in the recess 102.

### Method of Embedding Recess of One Embodiment

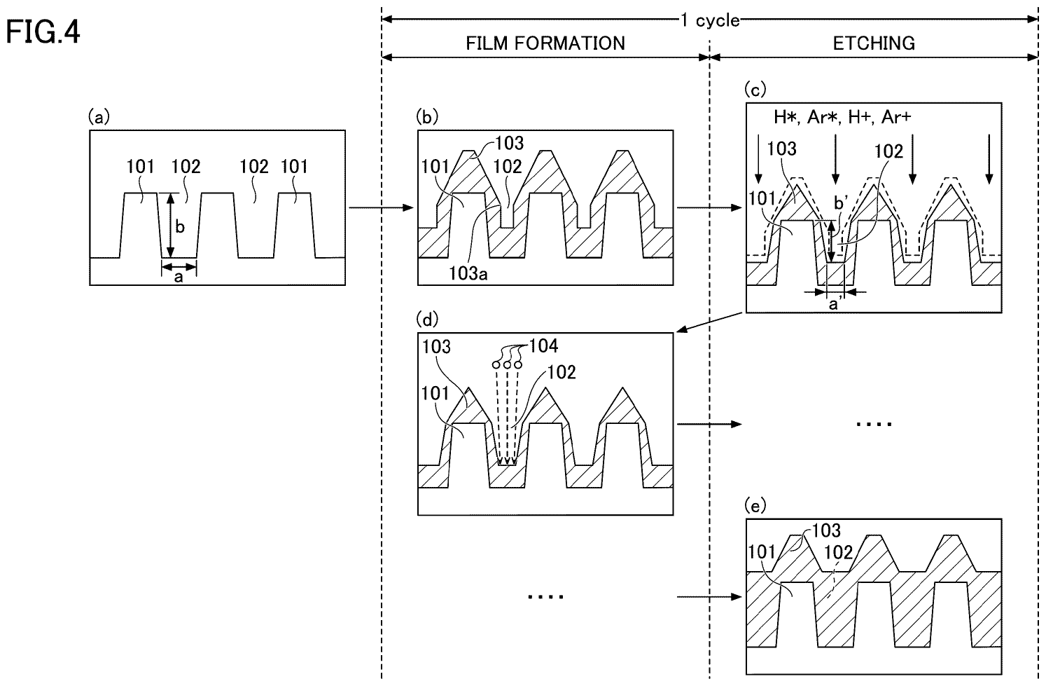

Therefore, in the present embodiment, a method of embedding for improving the accuracy of embedding the film in the recess 102 is proposed. The method of embedding a recess of one embodiment will be described with reference to FIG. 4. FIG. 4 is a schematic cross-sectional diagram illustrating an example of a film formed by the method of embedding a recess according to one embodiment.

In the method of embedding a recess according to one embodiment as well, the film forming process and the etching process are repeated a set number of times. In the film forming process, the microwave power is supplied into the process chamber 10 to generate the plasma of the gas containing the raw material gas. At this time, in the film forming process, the first DC pulse voltage is applied to the stage 11. In the etching process, the microwave power is supplied into the process chamber 10 to generate the plasma of the gas containing the etchant gas. At this time, in the etching process, the second DC pulse voltage is applied to the stage 11.

The first DC pulse voltage is set to a value in which the potential of the substrate W in the film forming process is selectively controlled to a potential that makes the dielectric film 103 have a desired shape. That is, when the film forming process is performed, the first DC pulse voltage is set to be a value in which the potential of the substrate W is selected to be a potential that optimizes the shape of the dielectric film 103. Thus, in the film state after the first film formation as illustrated in FIG. 4(b), the dielectric film 103 is deposited on the bottom surface, the side surface, and the top surface of the recess 102, and the dielectric film 103 deposited on the top surface can be formed in a triangular shape on the top surface. Thus, the opening of the recess 102 is less likely to be blocked by the dielectric film 103. In the following description, “the dielectric film 103 is formed in a triangular shape” means that the upper part of the dielectric film 103 has a pointed triangular shape or an approximately triangular shape in the longitudinal cross-sectional shape of the dielectric film 103.

When the protrusions of corners 103a of the triangle other than the tip of the dielectric film 103 become large, the opening of the recess 102 narrows. Therefore, the second DC pulse voltage is a value different from the first DC pulse voltage, and is set to a value that selectively controls the potential of the substrate in the etching process to a potential that makes the dielectric film 103 have a desired shape by etching.

Thus, a part of the dielectric film 103 including the corners 103a of the triangle other than the tip of the dielectric film 103 is etched. In the film state after the first etching illustrated in FIG. 4(c), the upper part and the sides of the dielectric film 103 are etched, so that the protrusion of the corner 103a is eliminated and the opening of the recess 102 is widened. Thus, the dielectric film 103 can be readily formed from the bottom of the recess 102 in the next film forming process, and the generation of voids can be suppressed.

When the aspect ratio (X′) of the recess 102 after the first etching illustrated in FIG. 4(c) is compared with the aspect ratio (X) in the initial state, it is X≈X′. In other words, the aspect ratio is approximately the same in the first cycle and the second cycle, and the dielectric film 103 can be formed from the bottom of the recess 102 even when the number of cycles increases. As a result, the generation of voids is suppressed compared with the conventional method of embedding a recess, and the accuracy of embedding the dielectric film 103 into the recess 102 can be improved.

In the second film formation, the active species 104 such as the precursors readily enter the recess 102, so that after the second film formation illustrated in FIG. 4(d), the dielectric film 103 is formed on the bottom surface, the side surface, and the top surface of the recess 102. In particular, the upper part of the dielectric film 103 deposited on the top surface can be formed in a triangular shape.

Further, by repeating the film forming process and the etching process, the recess 102 can be completely embedded with the dielectric film 103, as illustrated in FIG. 4(e). In the subsequent process, the dielectric film 103 illustrated in FIG. 4(e) is planarized by chemical mechanical polishing (CMP).

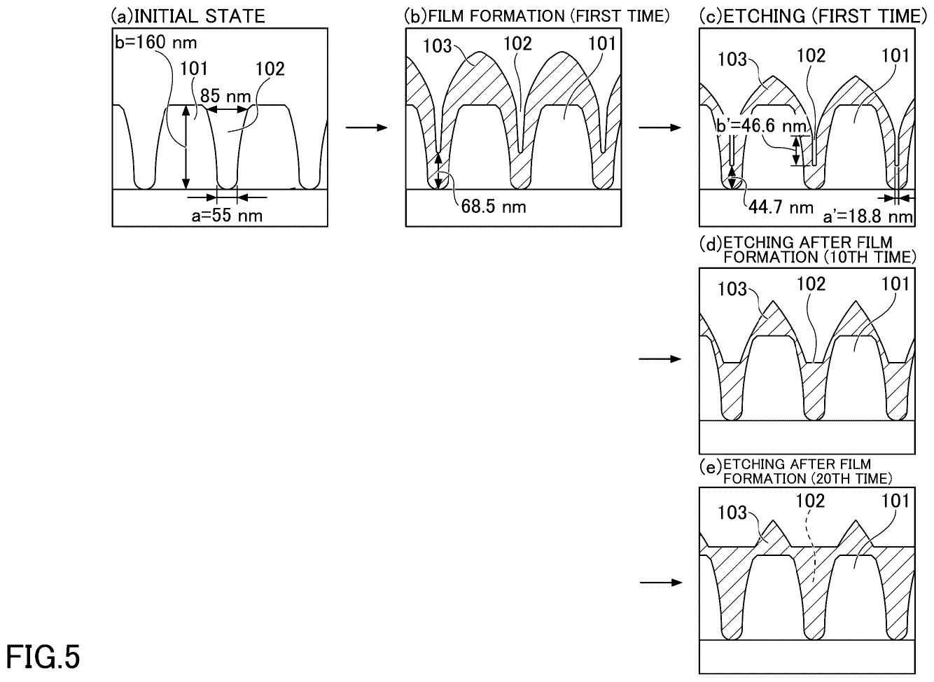

FIG. 5 is a traced image of an example of an SEM image of a film formed by the method of embedding a recess according to one embodiment. FIG. 5(a) illustrates the initial state of the substrate W before the film formation and etching. The width a of the bottom surface of the recess 102 was 55 nm, the length b of the side surface was 160 nm, and the aspect ratio (X) was 2.9. FIG. 5(b) illustrates the film state after the first film forming process, and the thickness of the dielectric film 103 at the bottom was 68.5 nm. Because the upper part of the dielectric film 103 has the triangular shape pointed upward, it is easier for the precursor to enter the bottom side of the recess 102 from the upper part and the sides of the dielectric film 103 than in the case where the upper part of the dielectric film 103 has a rounded and swollen shape as in the conventional case. As a result, the amount of the film formed at the bottom of the recess 102 increased by approximately three times as compared with the conventional case.

FIG. 5(c) illustrates the film state after the first etching process, and the thickness of the bottom of the dielectric film 103 was 44.7 nm. At this time, the width a′ of the bottom of the recess 102 was 18.8 nm, the depth b′ was 46.6 nm, and the aspect ratio (X′) was 2.5. The depth b′ is the length from the bottom to the corner (or the tip when there is no corner) of the side of the dielectric film 103.

FIG. 5(d) illustrates the film state after the etching process after 10 cycles, and the dielectric film 103 was further formed in the recess 102. FIG. 5(e) illustrates the state of the film after the etching process after 20 cycles, and the recess 102 was completely embedded with the dielectric film 103.

From the above, in the method of embedding a recess according to one embodiment, it was found that the aspect ratio remained approximately unchanged even when the number of cycles increased. Thus, it was possible to embed the dielectric film 103 without blocking the opening of the recess 102.

### Method of Embedding Recess

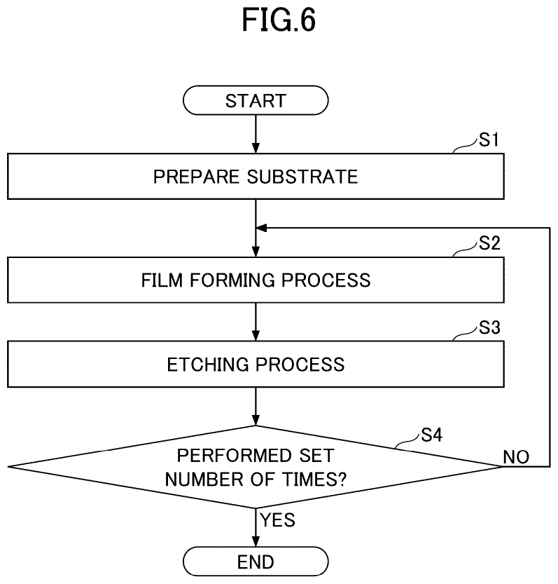

The method of embedding a recess according to one embodiment will be described with reference to FIG. 6. FIG. 6 is a flowchart illustrating an example of the method of embedding a recess according to one embodiment. This method of embedding is controlled by the controller 130 and may be performed by the plasma processing apparatus 1.

### Preparation Process

When this process starts, in step S1, the substrate W having the recess 102 is placed on the stage 11 in the process chamber 10 and prepared.

### Film Forming Process

Next, in step S2, a film forming process of forming the dielectric film 103 in the recess 102 of the substrate W is performed. In the film forming process, the gas containing the raw material gas is supplied into the process chamber 10. The microwave power is supplied into the process chamber 10 from the plurality of microwave radiation mechanisms 42 through the dielectric windows 56. Thus, a plasma of the gas containing the raw material gas is generated, and the dielectric film 103 is formed by precursors in the plasma.

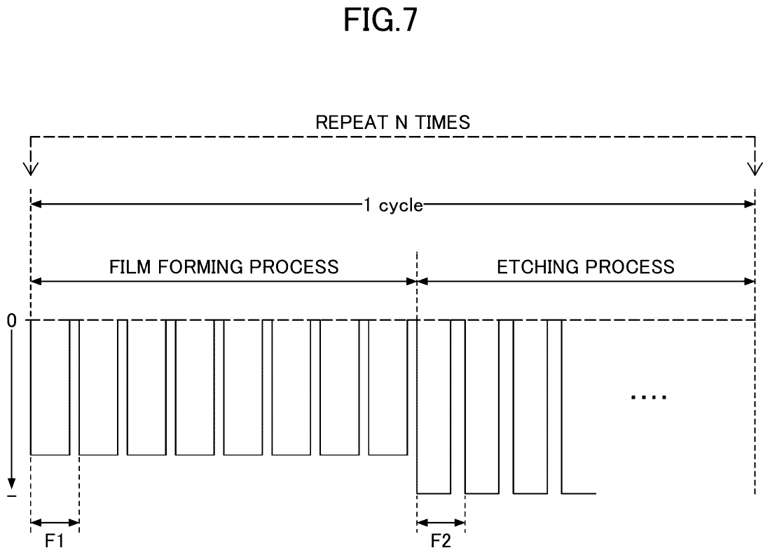

In addition, the first DC pulse voltage (pulsed DC voltage) is applied to the stage 11. The first DC pulse voltage is set to a value that selectively controls the potential of the substrate W in the film forming process to a potential that makes the dielectric film 103 have a desired shape. For example, FIG. 7 illustrates an example of waveforms of the first DC pulse voltage applied in the film forming process and the second DC pulse voltage applied in the etching process. In the film forming process, the first DC pulse voltage alternates between an ON state in which a negative voltage (for example, −300 V) is applied and an OFF state in which the voltage is 0 V. The first DC pulse voltage in the ON state may be −100 V to −800 V.

A pulse frequency F1 of the first DC pulse voltage may be, for example, 500 kHz. The pulse frequency F1 of the first DC pulse voltage may be 100 kHz to 1,000 KHz.

The duty ratio of the first DC pulse voltage may be, for example, 80%. The duty ratio is the ratio of the ON-state time to the total of the ON-state time and the OFF-state time of the first DC pulse voltage. The duty ratio of the first DC pulse voltage may be 10% to 90%. The time of the film forming process is set to a time such that the triangular shape of the upper part of the dielectric film 103 is not too sharp.

### Etching Process

Returning to FIG. 6, next, in step S3, an etching process of etching at least a part of the dielectric film 103 formed in the recess 102 of the substrate W is performed. In the etching process, the gas containing the etchant gas is supplied into the process chamber 10. The microwave power is supplied into the process chamber 10 from the plurality of microwave radiation mechanisms 42 through the dielectric windows 56. Thus, a plasma of the gas containing the etchant gas is generated, and the dielectric film 103 is etched by radicals, ions, and the like.

The second DC pulse voltage (pulsed DC voltage) is applied to the stage 11. The second DC pulse voltage is set to a value that selectively controls the potential of the substrate W in the etching process to a potential that makes the dielectric film 103 have a desired shape. The relationship between the values of the first DC pulse voltage and the second DC pulse voltage and the potential of the substrate W will be described later.

In the example illustrated in FIG. 7, in the etching process, the second DC pulse voltage alternates between an ON state in which a negative voltage (for example, −400 V) is applied and an OFF state in which the voltage is 0 V. The second DC pulse voltage in the ON state may be −100 V to −800 V.

A pulse frequency F2 of the second DC pulse voltage is, for example, 500 kHz. The pulse frequency F2 of the second DC pulse voltage may be 100 kHz to 1,000 KHz. The pulse frequency F1 of the first DC pulse voltage and the pulse frequency F2 of the second DC pulse voltage may be the same.

The duty ratio of the second DC pulse voltage is, for example, 80%. The duty ratio is the ratio of the ON-state time to the total of the ON-state time and the OFF-state time of the second DC pulse voltage. The duty ratio of the second DC voltage may be 10% to 90%. The duty ratio of the first DC pulse voltage and the duty ratio of the second DC pulse voltage may be the same. The time of the etching process is set to a time such that the base film 101 is not etched.

### Repeat Determination Process

Returning to FIG. 6, next, in step S4, it is determined whether one cycle of the film forming process and the etching process has been performed the set number of times n (n is plural). When it is determined that the set number of times n (n is plural) has not been performed, the process returns to step S2 and the next cycle of the film forming process and the etching process is performed. When it is determined that the set number of times n (n is plural) has been performed, the process ends. For example, when the aspect ratio is approximately three, the set number of times may be approximately 20, but is not limited thereto.

### Experimental Results of Film Forming Process

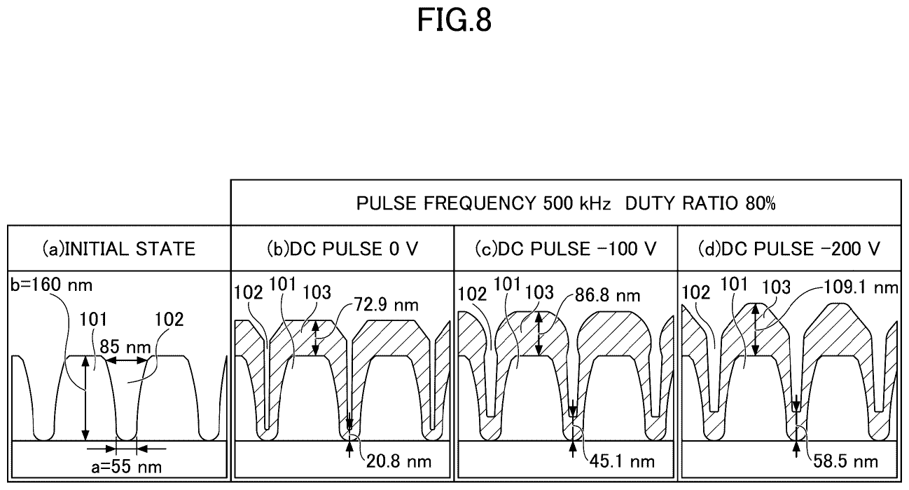

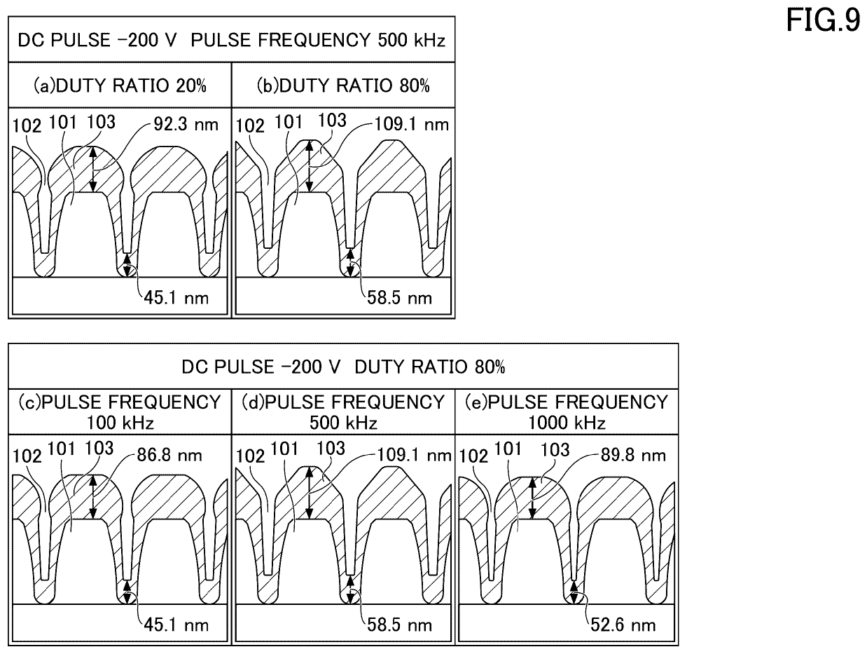

Next, the experimental results when at least one of the DC pulse voltage, the pulse frequency F1, and the duty ratio is variably controlled in the film forming process will be described with reference to FIGS. 8 and 9. FIGS. 8 and 9 are traced images of an example of an SEM image after the first film forming process according to one embodiment. FIG. 8 illustrates a film formation result 1 of Experiment 1, and FIG. 9 illustrates a film formation result 2 of Experiment 2. A process condition 1 of Experiment 1 illustrated in FIG. 8 is as follows.

### Process Condition 1

Gas containing raw material gas: NH₃ gas, SiH₄ gas, Ar gas
Pulse frequency F1: 500 KHz
Duty ratio: 80%
DC pulse voltage (first DC voltage): variable (0 V, −100 V, −200 V)
Microwave power: 2,000 to 6,000 W

### Film Formation Result 1

FIG. 8(a) illustrates the initial state of the substrate before the film forming process and the etching process. The width a of the bottom surface was 55 nm, the depth b was 160 nm, and the aspect ratio (X) was 2.9. FIG. 8(b) illustrates the film state after the first film formation when the DC pulse voltage (first DC voltage) was 0 V, that is, when the DC pulse voltage was not applied. When the DC pulse voltage was not applied, the dielectric film 103 with a thickness of 20.8 nm was formed at the bottom of the recess.

FIG. 8(c) illustrates the state of the film after the first film formation when the DC pulse voltage was −100 V. When the DC pulse voltage of −100 V was applied, the dielectric film 103 with a thickness of 45.1 nm was formed at the bottom of the recess 102.

FIG. 8(d) illustrates the state of the film after the first film forming process when the DC pulse voltage was −200 V. When the DC pulse voltage of −200 V was applied, the dielectric film 103 with a thickness of 58.5 nm was formed at the bottom of the recess 102. In addition, as illustrated in FIG. 8(d), it was possible to make the upper part of the dielectric film 103 have the desired shape (triangular shape). In other words, the more negative the DC pulse voltage, the sharper the triangular shape at the upper part of the dielectric film 103.

From the above, it is considered that it is possible to control the triangular shape at the upper part of the dielectric film 103 by attracting positive ions in the plasma by applying the DC pulse voltage of negative polarity to the stage 11. Next, a process condition 2 of Experiment 2 is described.

### Process Condition 2

Gas containing raw material gas: NH₃ gas, SiH₄ gas, Ar gas
Pulse frequency F1: variable (100 kHz, 500 kHz, 1,000 kHz)
Duty ratio: variable (20%, 80%)
DC pulse voltage (first DC voltage): −200 V
Microwave power: 2,000 to 6,000 W

### Film Formation Result 2

FIGS. 9(a) and (b) illustrate the film state after the first film formation when the DC pulse voltage is set to −200 V, the pulse frequency F1 is set to 500 kHz, and the duty ratios are set to 20% and 80%. According to this, when the duty ratio was 80% in FIG. 9(b), the upper part of the dielectric film 103 became close to an ideal triangular shape, and because the active species can easily enter into the bottom of the recess 102, the amount of film formed at the bottom of the recess 102 increased. When the duty ratio was 20% in FIG. 9(a), the upper part of the dielectric film 103 became rounded, and also the amount of film formed at the bottom of the recess 102 was smaller than when the duty ratio was 80%. Thus, when the duty ratio was 80%, more favorable results were obtained than when the duty ratio was 20% as illustrated in FIG. 9(a).

FIG. 9(c) to (e) illustrate the film state after the first film forming process when the DC pulse voltage was set to −200 V, the duty ratio was set to 80%, and the pulse frequency F1 was set to 100 kHz, 500 kHz, and 1,000 kHz. According to this, when the pulse frequency F1 was set to 500 KHz in FIG. 9(d), the upper part of the dielectric film 103 became an ideal triangular shape, and the dielectric film 103 having a thickness of 58.5 nm was formed at the bottom of the recess 102. More favorable results were obtained in both the shape of the upper part of the dielectric film 103 and the amount of film formed at the bottom of the recess 102 than when the pulse frequency F1 was set to 100 kHz and 1,000 kHz as illustrated in FIGS. 9(c) and (e). In other words, it is found that, when the DC pulse voltage is −200 V, the pulse frequency F1 is preferably 500 kHz, and the upper part of the dielectric film 103 is moved away from the ideal triangular shape and the amount of the dielectric film 103 formed on the bottom of the recess 102 is reduced when the pulse frequency F1 is too short or too long relative to 500 kHz.

In the film forming process, a favorable triangular shape of the dielectric film 103 can be obtained by setting the first DC voltage to a value within the range of −100 V to −800 V, whereby the tendency of the potential of the substrate W to be selected described later can be obtained.

### Experimental Results of Etching Process

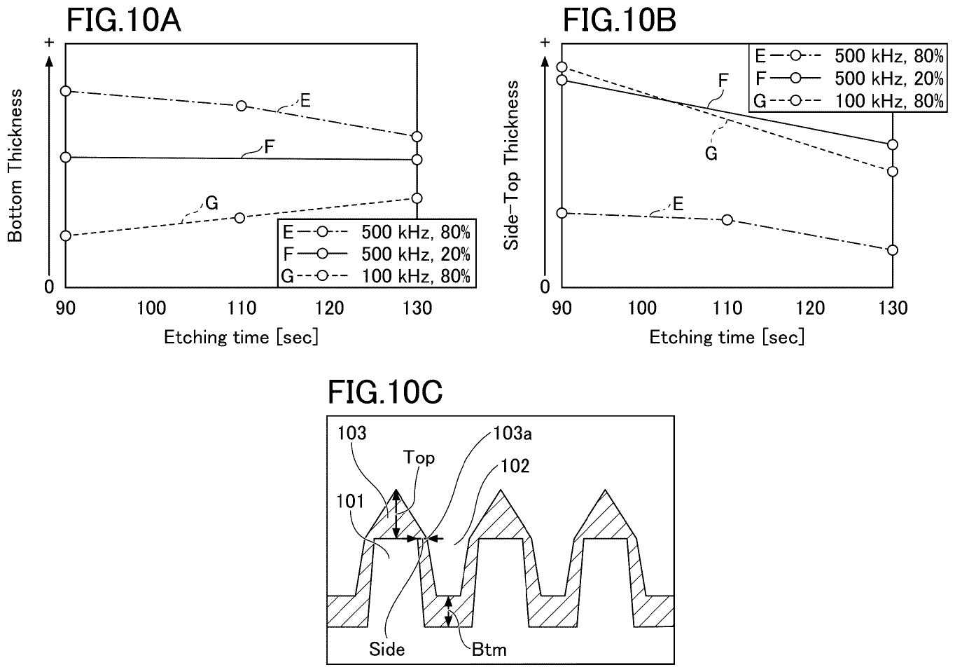

Next, the experimental results when at least one of the pulse frequency F2 and the duty ratio is variably controlled in the etching process will be described with reference to FIGS. 10A, 10B, and 10C. FIG. 10C is a traced image of an example of an SEM image after the first etching process according to one embodiment, and illustrates an etching result 3 of Experiment 3. A process condition 3 of Experiment 3 is as follows.

### Process condition 3

Gas containing etchant gas: Ar gas, H₂ gas
Pulse frequency F2: variable (100 kHz, 500 kHz)
Duty ratio: variable (20%, 80%)
DC pulse voltage (second DC voltage): −800 V
Microwave power: 150 to 3,000 W

### Etching Result 3

The change in the thickness of the bottom of the dielectric film 103 when the etching time of the first etching process was changed was observed. In FIG. 10A, the horizontal axis indicates the etching time, and the vertical axis indicates the thickness of the bottom of the dielectric film 103 after etching the recess 102. The thickness of the bottom indicates the thickness of the dielectric film 103 from the bottom of the recess 102, as indicated by “Btm” in FIG. 10C.

In FIG. 10A, a line E indicates the thickness of the bottom when the pulse frequency F2 and the duty ratio are 500 kHz and 80%, a line F indicates the thickness of the bottom when the pulse frequency F2 and the duty ratio are 500 kHz and 20%, and a line G indicates the thickness of the bottom when the pulse frequency F2 and the duty ratio are 100 kHz and 80%.

When the pulse frequency F2 was 500 kHz and the duty ratio was 80% as indicated by the line E, the thickness of the bottom decreased as the etching time increased. When the pulse frequency F2 was 500 kHz and the duty ratio was 20% as indicated by the line F, the thickness of the bottom did not change even with increase in the etching time. When the pulse frequency F2 was 100 kHz and the duty ratio was 20% as indicated by the line G, the thickness of the bottom increased as the etching time increased.

The thickness of the bottom increased relatively when the pulse frequency F2 was 500 kHz and the duty ratio was 80% as indicated by the line E, and decreased when the pulse frequency F2 was 100 kHz and the duty ratio was 20% as indicated by the line G. That is, when the pulse frequency F2 was 500 kHz and the duty ratio was 80% as indicated by the line F, the thickness of the dielectric film 103 formed at the bottom of the recess 102 was thick. In other words, the etching amount of the dielectric film 103 formed at the bottom of the recess 102 was small. In addition, as indicated by the line F, even when the pulse frequency F2 was 500 kHz, when the duty ratio decreased to 20%, the thickness of the bottom decreased. In other words, the etching amount of the dielectric film 103 formed at the bottom of the recess 102 increased. In addition, as indicated by the line G, even when the duty ratio was 80%, when the pulse frequency F2 was as low as 100 kHz, the dielectric film 103 at the bottom was etched, and the thickness of the bottom decreased further. In other words, the etching amount of the dielectric film 103 formed at the bottom of the recess 102 increased.

Therefore, in the etching process, when the pulse frequency F2 was decreased, the etching amount increased, so that the thickness of the bottom became thinner. When the duty ratio was decreased, the etching amount slightly increased, so that the thickness of the bottom became thinner. When the pulse frequency F2 was 500 kHz and the duty ratio was 80%, the etching amount decreased as the etching time was shorter, so that the thickness of the bottom became thicker. Therefore, it is preferable to set the pulse frequency F2 to 500 kHz and the etching time to 90 seconds to reduce the etching amount of the dielectric film 103 formed at the bottom of the recess 102. In addition, it is preferable to set the duty ratio to 80% rather than 20%. Although not illustrated, when the pulse frequency F2 was set to 500 kHz, a favorable triangular shape at the upper part of the dielectric film 103 was obtained.

In FIG. 10B, the horizontal axis indicates the etching time, and the vertical axis indicates the thickness of the side relative to the thickness of the top. The thickness of the top indicates the thickness from the top surface of the recess 102 to the tip of the dielectric film 103, as indicated by “Top” in FIG. 10C. The thickness of the side indicates the thickness of the dielectric film 103 in the horizontal direction from the corner 103a of the triangular side of the dielectric film 103 to the side surface of the recess 102, as indicated by “Side” in FIG. 10C.

Similarly to FIG. 10A, in FIG. 10B, the thickness of the side relative to the thickness of the top is indicated by the line E when the pulse frequency F2 and the duty ratio are 500 KHz and 80%, by the line F when the pulse frequency F2 and the duty ratio are 500 kHz and 20%, and by the line G when the pulse frequency F2 and the duty ratio are 100 kHz and 80%.

According to this, in all cases, the thickness of the side relative to the thickness of the top decreased as the etching time increased. In addition, when the pulse frequency F2 and the duty ratio are 500 kHz and 80% as indicated by the line E, the thickness of the side relative to the thickness of the top became the thinnest. That is, when the pulse frequency F2 and the duty ratio are 500 kHz and 80%, the thickness from the corner 103a of the dielectric film 103 to the recess 102 is the thinnest, and the opening of the recess 102 can be widened by etching. However, when the thickness of the side relative to the thickness of the top is 0 or less, the base film 101 is etched.

When the pulse frequency F2 and the duty ratio are 500 kHz and 20% as indicated by the line F, and when the pulse frequency F2 and the duty ratio are 100 kHz and 80% as indicated by the line G, the thickness of the side relative to the thickness of the top became thicker than that of the line E. In these cases, the effect of widening the opening of the recess 102 by etching was lower than when the pulse frequency F2 was 500 kHz and the duty ratio was 80% as indicated by the line E.

Therefore, in the etching process, the thickness of the side relative to the thickness of the top became thicker when the pulse frequency F2 was decreased. In addition, the thickness of the side relative to the thickness of the top became thicker when the duty ratio was decreased. Therefore, it is preferable to set the pulse frequency F2 to 500 kHz and the duty ratio to 80% in the etching process because the opening of the recess 102 can be widened and the risk of etching the base film 101 is low. It is preferable to set the duty ratio to 80% rather than 20%.

In the etching process, a favorable triangular shape of the dielectric film 103 can be obtained by setting the second DC pulse voltage to a value within the range of −100 V to −800 V, whereby the tendency of the potential of the substrate W to be selected described later can be obtained.

### Application of DC Pulse Voltage and Waveform of Substrate Potential

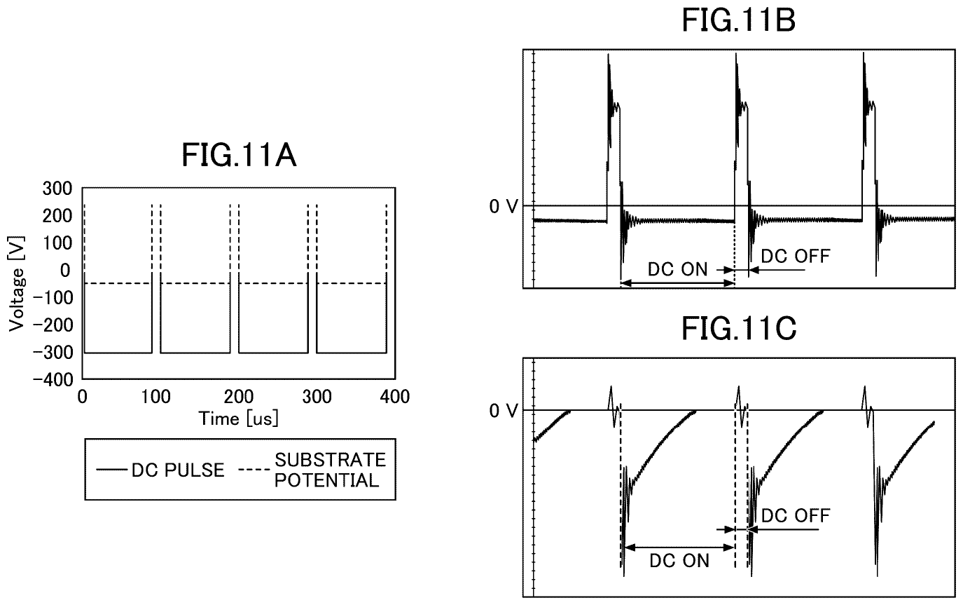

The measurement result of the waveform of the substrate potential when the DC pulse voltage is applied to the stage 11 will be described. FIGS. 11A, 11B, and 11C are diagrams illustrating an example of the DC pulse voltage and the substrate potential according to one embodiment. As illustrated in FIG. 1, the substrate potential is measured by holding a high voltage (HV) probe 90 between the substrate W and the stage 11. The waveforms of the DC pulse voltage (DC pulse) and the measured substrate potential (voltage) were displayed on an oscilloscope 91 (see FIGS. 11B and 11C).

In FIG. 11A, the solid line indicates the ideal waveform of the DC voltage when the DC voltage of −300 V is supplied from the DC power source 14 (see FIG. 1) and pulsed by the pulse generator 13, and the dashed line indicates the ideal potential of the substrate W when the ideal DC voltage of this waveform is applied to the stage 11.

With respect to the ideal potential of the substrate W illustrated in FIG. 11A, FIGS. 11B and 11C illustrate the potential of the substrate W actually measured by the HV probe 90 and displayed on the oscilloscope 91. FIG. 11B illustrates the potential of the substrate W when the plasma is not generated in the plasma processing apparatus 1. FIG. 11C illustrates the potential of the substrate W when the plasma is generated in the plasma processing apparatus 1.

In both cases where the plasma is not generated and where the plasma is generated, the potential of the substrate W has a negative value when the DC voltage is ON (DC ON), and the potential of the substrate W has a substantially positive value when the DC voltage is OFF (DC OFF).

When the plasma is not generated as illustrated in FIG. 11B, the potential of the substrate W has the same waveform as the potential of the substrate W illustrated in FIG. 11A. In contrast, when the plasma is generated as illustrated in FIG. 11C, positive ions in the plasma flow towards the substrate W while the DC voltage of −300 V is ON. Therefore, when the DC voltage of −300 V is ON, the negative potential of the substrate W has a waveform that gradually relaxes.

### Application of DC Pulse Voltage and Tendency of Substrate Potential to be Selected

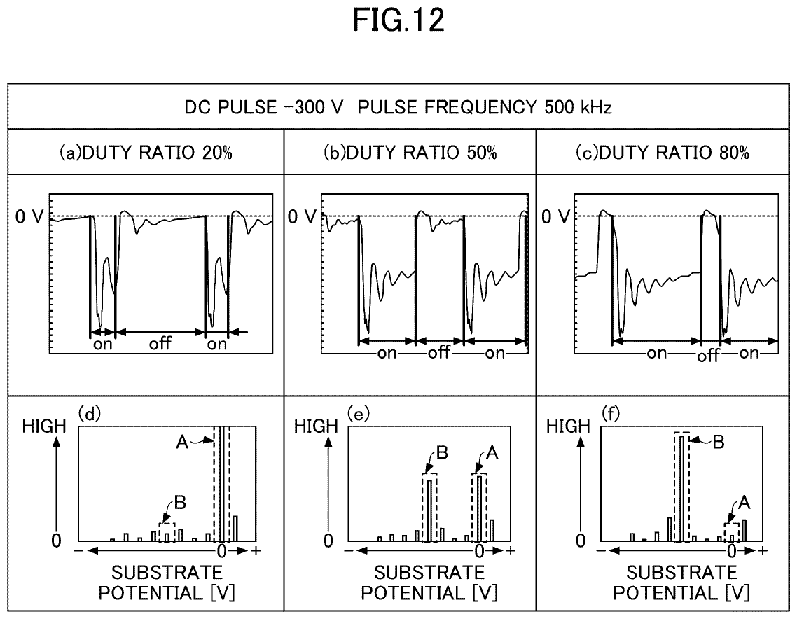

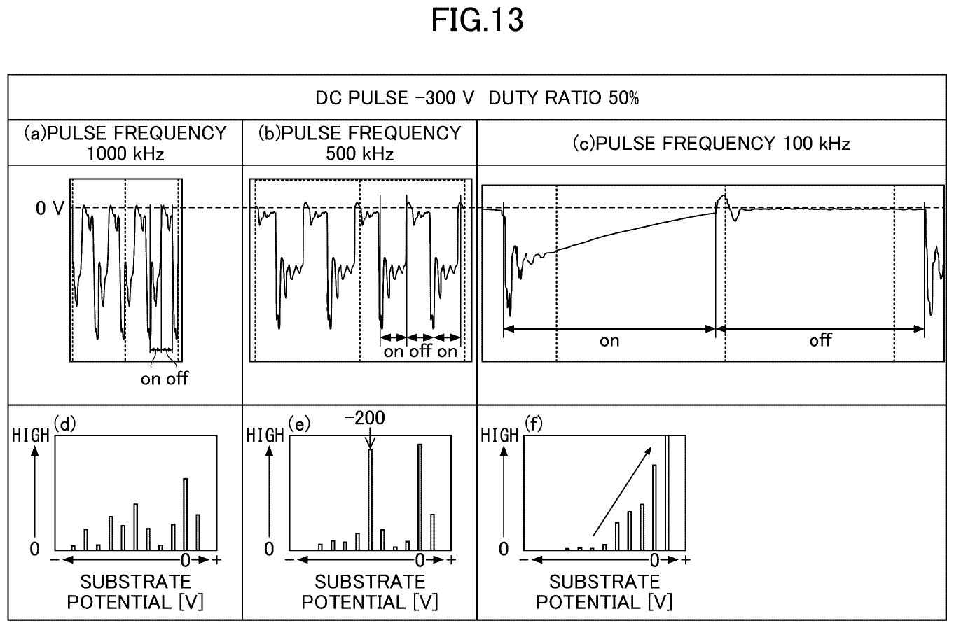

The application of the DC pulse voltage and the tendency of the substrate potential to be selected will be described with reference to FIGS. 12 and 13. FIGS. 12 and 13 illustrate an example of the DC pulse voltage and the tendency of the substrate potential to be selected according to one embodiment.

FIG. 12(a) to (c) are examples of waveforms of the DC pulse voltage of −300 V applied to the stage 11 in the film forming process. The DC pulse voltage (first DC pulse voltage) is controlled at −300 V in the ON state and 0 V in the OFF state. The duty ratios of the DC pulse voltages in FIGS. 12(a) to (c) are 20%, 50%, and 80%. Other process conditions are as follows.

### Process Conditions

Gas containing raw material: N₂ gas, Ar gas
Pulse frequency F1: 500 kHz
Microwave power: 700 W

### Substrate Potential Result 1

In FIG. 12(d) to (f), the horizontal axis indicates the potential of the substrate W measured by the HV probe 90, and the vertical axis indicates the tendency of the measured potential to be selected. That is, the vertical axis indicates the percentage of the potential during the film forming process, and a larger value (higher bar graph height) indicates the potential that tends to be selected as the potential of the substrate W during the film forming process. A indicates when the potential of the substrate W is 0 V, and B indicates when the potential of the substrate W is −200 V. The potential of B is an example.

When the duty ratio is 20% as illustrated in FIG. 12(d), most of the potential of the substrate W is controlled to 0 V as indicated by A. The other potentials including B have a low bar graph height and do not tend to be selected as the potential of the substrate W during the process. It is considered that the potential in the ON state did not stabilize because the ON-state time was too short and it turned off before the potential stabilized.

When the duty ratio was 50% as illustrated in FIG. 12(e), most of the potential of the substrate W was controlled to 0 V as indicated by A and −200 V as indicated by B. When the first DC pulse voltage was −300 V, the pulse frequency F1 was 500 kHz, and the duty ratio was 50%, it was found that the potential of the substrate W in the ON state tended to be selected at −200 V.

When the duty ratio was 80% as illustrated in FIG. 12(f), most of the potential of the substrate W was controlled to −200 V as indicated by B. Therefore, when the first DC pulse voltage was −300 V, the pulse frequency F1 was 500 kHz, and the duty ratio was 80%, it was found that the potential of the substrate W in the ON state tended to be selected at −200 V. In the conditions for obtaining the results of FIGS. 12(e) and (f), because the tendency for the potential of −200 V to be selected is high, it is possible to control the triangular shape corresponding to the potential of −200 V selected as the potential of the substrate W with high accuracy.

In this manner, the shape of the dielectric film 103 can be controlled to the desired shape (ideal triangle shape) by controlling the first DC pulse voltage and controlling the potential of the substrate W to the target potential in the film forming process such that the shape of the dielectric film 103 becomes the desired shape.

Similarly, in the etching process as well, the shape of the dielectric film 103 can be etched to the desired shape (ideal triangle shape) by controlling the second DC pulse voltage and controlling the potential of the substrate W to the target potential.

In FIG. 13, the duty ratio was controlled at 50% and the pulse frequency was variably controlled under the same process conditions as those of the film forming process described with reference to FIG. 12. FIG. 13(a) to (c) illustrate the results of controlling the pulse frequency F1 at 1,000 kHz, 500 kHz, and 100 kHz.

FIG. 13(a) to (c) are examples of waveforms of the DC pulse voltage of −300 V applied to the stage 11 in the film forming process. In FIG. 13(d) to (f), the horizontal axis indicates the potential of the substrate W measured by the HV probe 90, and the vertical axis indicates the tendency of the potential to be selected. In other words, the vertical axis indicates the percentage of the potential during the film forming process, and a larger value (higher bar graph height) indicates the potential that tends to be selected as the potential of the substrate W during the film forming process.

When the pulse frequency was 1,000 kHz as illustrated in FIG. 13(d), the pulse frequency period was too short and the potential was turned off before the potential was stabilized, so the potential in the ON state was not stabilized. Therefore, there was no potential that tended to be selected as the potential of the substrate W.

When the pulse frequency was 500 kHz as illustrated in FIG. 13(e), most of the potential of the substrate W was controlled at 0 V and −200 V. When the first DC pulse voltage was −300 V, the pulse frequency F1 was 500 kHz, and the duty ratio was 50%, there was a tendency of the potential of the substrate W to be selected.

When the pulse frequency was 100 kHz as illustrated in FIG. 13(f), because the pulse frequency period was long, the DC pulse voltage was in the ON state for a long time, ions were injected into the substrate W during the ON-state time, and the potential of the substrate W increased gradually. Accordingly, the tendency to be selected disappeared.

From the above, in order to obtain the desired shape of the dielectric film 103 in the film forming process, it is important to control the frequency of the first DC voltage such that the potential of the substrate W is selectively controlled to the potential that makes the dielectric film 103 have the desired shape.

Similarly, in order to obtain the desired shape of the dielectric film 103 in the etching process, it is important to control the frequency of the second DC voltage such that the potential of the substrate W is selectively controlled to the potential that makes the dielectric film 103 have the desired shape.

### Comparison with RF Pulse Power

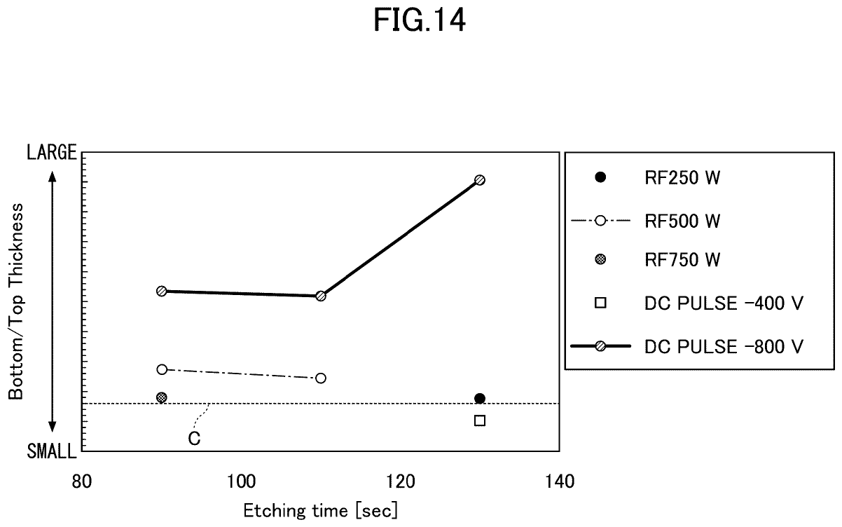

Referring to FIG. 14, the thickness of the bottom relative to the thickness of the top of the dielectric film 103 when the method of embedding of the present embodiment in which the second DC pulse voltage is applied in the etching process and the method of embedding of the reference example in which the RF pulse power is applied in the etching process are performed will be described. FIG. 14 is a diagram illustrating an example of the thickness of the bottom relative to the thickness of the top of the dielectric film 103 when the second DC pulse voltage and the RF pulse power are used.

In FIG. 14, the horizontal axis indicates the etching time, and the vertical axis indicates the thickness of the bottom relative to the thickness of the top (see “Top” and “Btm” in FIG. 10C). The RF pulse power is obtained by providing an RF power source instead of the DC power source (FIG. 1), and the RF power is pulsed by a pulse generator. Both the second DC pulse voltage and the RF pulse power are supplied to the stage 11. The pulse frequency and duty ratio of the second DC pulse voltage and the RF pulse power are controlled to be the same.

As illustrated in FIG. 14, for example, in the case where the RF pulse power of 500 W and the second DC pulse voltage of −800 V are respectively supplied, the thickness of the bottom relative to the thickness of the top is larger when the second DC pulse voltage of −800 V is supplied. That is, when the second DC pulse voltage of −800 V is supplied, it was found that the selective etching was possible in which the top was etched more than the bottom.

When the RF pulse power was supplied, not only the top but also the bottom of the dielectric film 103 were etched and became thinner. Although not illustrated, other experiments indicated that the negative second DC pulse voltage can etch the side of the dielectric film 103 (see “Side” in FIG. 10C) more smoothly than the RF pulse power. Thus, it is possible to form an ideal triangular shape of the dielectric film 103 that facilitates the film formation at the bottom of the recess 102.

At least either of the first DC voltage and the second DC voltage may be changed according to an increase in the number of times the film forming process and the etching process are repeated. For example, in consideration of the fact that the width of the recess 102 becomes narrower as the number of cycles (the number of times of repetition) increases, the values of the first DC voltage and the second DC voltage may be increased according to an increase in the number of cycles in order to increase the etching force, and the force of attraction of ions may be controlled so as to increase.

At least either of the pulse frequency of the first DC voltage and the pulse frequency of the second DC voltage may be changed according to an increase in the number of times the film forming process and the etching process are repeated. At least either of the duty ratio of the first DC voltage or the duty ratio of the second DC voltage may be changed in accordance with an increase in the number of times of the film forming process and the etching process are repeated.

Thus, the first DC voltage and the second DC voltage can be adjusted to the potential of the substrate W forming the dielectric film 103 having an ideal triangular shape.

Based on the results of the experiments described above, the first DC voltage may be in the range of −100 V to −800 V. The second DC voltage may be in the range of −100 V to −800 V. The first DC voltage and the second DC voltage may be set to values within each range, and the pulse frequency and the duty ratio may be controlled as follows.

In the film forming process and the etching process, the pulse frequency and the duty ratio may be controlled to any combination of 100 kHz and 20%, 200 kHz and 20%, 500 kHz and 50% to 90%, and 1,000 kHz and 80% to 90%.

The time in which the first DC voltage is in the ON state and the time in which the second DC voltage is in the ON state may be within the range of 0.7 μsec to 2.0 μsec. Thus, the potential of the substrate W can be selectively controlled in the film forming process to form the dielectric film 103 having an ideal triangular shape, and the film formation amount can be increased. Furthermore, the potential of the substrate W can be selectively controlled in the etching process to etch the dielectric film 103 having an ideal triangular shape.

As described above, according to the method of embedding a recess and the plasma processing apparatus of the present embodiment, the accuracy of embedding the film into the recess on the substrate can be increased.

The method of embedding a recess and the plasma processing apparatus of the present embodiment should be considered to be exemplary in all respects and not restrictive. The embodiments can be modified and improved in various forms without departing from the scope and spirit of the appended claims. The matters described in the above plurality of embodiments may have other configurations without contradiction, and can be combined without contradiction.

What is claimed is:

1. A method of embedding a recess, comprising:
preparing a substrate having a recess on a stage in a process chamber;
applying a pulsed first direct current (DC) voltage to the stage to form a dielectric film in the recess by a plasma generated from a gas containing a raw material gas supplied into the process chamber;
applying a pulsed second DC voltage to the stage to etch at least a part of the dielectric film formed in the recess by a plasma generated from a gas containing an etchant gas supplied into the process chamber; and
repeating the forming of the dielectric film and the etching of the dielectric film, wherein
the first DC voltage is set to a value in which a potential of the substrate in the forming of the dielectric film is selectively controlled to a potential that makes the dielectric film have a desired shape, and
the second DC voltage is a value different from the first DC voltage and is set to a value in which a potential of the substrate in the etching of the dielectric film is selectively controlled to a potential that makes the dielectric film have a desired shape.

2. The method of embedding the recess according to claim 1, wherein
an absolute value of the second DC voltage is larger than an absolute value of the first DC voltage.

3. The method of embedding the recess according to claim 2, wherein
the first DC voltage is −100 V to −800 V, and the second DC voltage is −100 V to −800 V.

4. The method of embedding the recess according to claim 1, wherein
a pulse frequency of the first DC voltage is 100 kHz to 1,000 KHz.

5. The method of embedding the recess according to claim 1, wherein
a pulse frequency of the second DC voltage is 100 kHz to 1,000 KHz.

6. The method of embedding the recess according to claim 1, wherein
a pulse frequency of the first DC voltage and a pulse frequency of the second DC voltage are same.

7. The method of embedding the recess according to claim 1, wherein
a duty ratio of the first DC voltage is 10% to 90%.

8. The method of embedding the recess according to claim 1, wherein
a duty ratio of the second DC voltage is 10% to 90%.

9. The method of embedding the recess according to claim 1, wherein
a duty ratio of the first DC voltage and a duty ratio of the second DC voltage are same.

10. The method of embedding the recess according to claim 1, wherein
the gas containing the raw material gas supplied in the forming of the dielectric film includes a silicon-containing gas and a gas containing at least one of nitrogen, oxygen, and carbon.

11. The method of embedding the recess according to claim 1, wherein
in the forming of the dielectric film, a microwave power is supplied into the process chamber to generate the plasma of the gas containing the raw material gas.

12. The method of embedding the recess according to claim 1, wherein
the dielectric film is a silicon-containing film.

13. The method of embedding the recess according to claim 12, wherein
the silicon-containing film is any one of SiO₂, SiN, SiON, SiCN, SiOC, and SiOCN.

14. The method of embedding the recess according to claim 1, wherein
the gas containing the etchant gas supplied in the etching of the dielectric film is at least one of an Ar gas, a mixed gas of Ar and N₂, a mixed gas of Ar and NH₃, a H₂ gas, a mixed gas of H₂ and N₂, or a mixed gas of H₂ and NH₃.

15. The method of embedding the recess according to claim 1, wherein
in the etching of the dielectric film, a microwave power is supplied into the process chamber to generate the plasma of the gas containing the etchant gas.

16. The method of embedding the recess according to claim 1, wherein
at least one of the first DC voltage and the second DC voltage is changed in accordance with an increase in a number of repetitions of the forming of the dielectric film and the etching of the dielectric film.

17. The method of embedding the recess according to claim 1, wherein
at least one of a pulse frequency of the first DC voltage and a pulse frequency of the second DC voltage is changed in accordance with an increase in a number of repetitions of the forming of the dielectric film and the etching of the dielectric film.

18. The method of embedding the recess according to claim 1, wherein
at least one of a duty ratio of the first DC voltage and a duty ratio of the second DC voltage is changed in accordance with an increase in a number of repetitions of the forming of the dielectric film and the etching of the dielectric film.

19. The method of embedding the recess according to claim 1, wherein
a time during which the first DC voltage is in an ON state and a time during which the second DC voltage is in an ON state are respectively within a range of 0.7 μsec to 2.0 μsec.

20. A plasma processing apparatus, comprising:
a process chamber;
a stage arranged in the process chamber and configured to mount a substrate thereon;
a DC voltage source configured to supply a DC voltage to the stage;
a top wall facing the stage;
a first gas supply arranged on the top wall and configured to supply a gas;
a second gas supply arranged on a side wall of the process chamber and configured to supply a gas;
a plasma source configured to generate a plasma in the process chamber through the top wall; and
a controller, the controller including a memory and a processor connected to the memory, and the processor being configured to:
prepare the substrate having a recess on the stage in the process chamber;
apply a pulsed first DC voltage to the stage to form a dielectric film in the recess by a plasma generated from a gas containing a raw material gas supplied into the process chamber;
apply a pulsed second DC voltage to the stage to etch at least a part of the dielectric film formed in the recess by a plasma generated from a gas containing an etchant gas supplied into the process chamber; and
repeat the forming of the dielectric film and the etching of the dielectric film, wherein
the first DC voltage is set to a value in which a potential of the substrate in the forming of the dielectric film is selectively controlled to a potential that makes the dielectric film have a desired shape, and
the second DC voltage is a value different from the first DC voltage and is set to a value in which a potential of the substrate in the etching of the dielectric film is selectively controlled to a potential that makes the dielectric film have a desired shape.
